(19) United States
(12) Patent Application Publication
(10) Pub. No.: US 2025/0254918 A1
(43) Pub. Date: Aug. 7, 2025

(54) STACKED FIELD EFFECT TRANSISTORS WITH CLADDING SILICON GERMANIUM PFET CHANNEL

(71) Applicant: International Business Machines Corporation, Armonk, NY (US)

(72) Inventors: Tsung-Sheng Kang, Ballston Lake, NY (US); Alexander Reznicek, Troy, NY (US); Ruilong Xie, Niskayuna, NY (US); Sagarika Mukesh, ALBANY, NY (US)

(21) Appl. No.: 18/434,787

(22) Filed: Feb. 6, 2024

(51) Int. Cl. H01L 29/423; H01L 21/8238; H01L 27/092; H01L 29/06; H01L 29/66; H01L 29/775; H01L 29/786

(52) U.S. Cl. CPC H10D 30/6735; H10D 30/014; H10D 30/43; H10D 30/6757; H10D 62/115; H10D 62/118; H10D 64/018; H10D 84/0167; H10D 84/038; H10D 84/856

(57) ABSTRACT

A semiconductor structure including a substrate, a first stack of channel layers on the substrate and a second stack of channel layers vertically aligned above the first stack. The width of the first is greater than the second. Additionally, the first channel layers can be cladded with germanium while the second channel layers can have a dog-bone shape.

### BACKGROUND

The present invention relates generally to the electrical, electronic and computer arts and, more particularly, to monolithic stacked nanosheet gate-all-around (GAA) field effect transistors (FETs) and the like, and to techniques for making same.

Historically, field effect transistor (FET) performance has been increased by lithographically shrinking the size of the transistors that are placed side-by-side. In the past, to further increase transistor density per unit area, transistors made on different substrates have been bonded together.

### BRIEF SUMMARY

Principles of the invention provide techniques for stacked field effect transistors (FETs) with cladding silicon germanium (SiGe) PFET (p-type FET) channel. In one aspect, an exemplary semiconductor structure includes a substrate, a first channel stack on the substrate having one or more first channel layers and having a first width, a second channel stack having one or more channel layers and having a second width wherein the second channel stack is vertically aligned above the first channel stack, and in which the first width is greater than the second width. The first channel stack can be part of a p-type field effect transistor while the second channel stack can be part of an n-type field effect transistor.

In another aspect, a semiconductor structure includes a substrate, a gate material, a p-type field effect transistor (PFET) on the substrate, an n-type field effect transistor (NFET) on the PFET, a middle dielectric isolation layer separating the PFET stack and the NFET stack. The PFET includes a p-doped source drain and a PFET stack which includes two or more first channel layers, each layer having two first extension regions on either side of a first channel region, in which the first extension region comprises silicon and the first channel region comprises silicon germanium and in which the first extension region and the first channel region have the same height. The PFET also includes a first inner spacer in contact with and above and below each first extension region. The gate material wraps the first channel region. The NFET includes an n-doped source drain, and an NFET stack comprising two or more silicon channel layers, each layer having two second extension regions on either side of a second channel region, wherein a second extension region height is greater than a second channel region height. The NFET also includes a second inner spacer in contact with and above and below each second extension region. The gate material wraps the second channel region. In which the second extension region height can be greater than the first extension region height, a first inner spacer thickness can be greater than a second inner spacer thickness, a second channel layer width is less than a middle dielectric isolation width and a first channel layer width is the same as the middle dielectric isolation width.

An exemplary method of forming a stacked NFET on PFET on substrate, includes forming a first nanostack of alternating layers of a first sacrificial material and a first silicon channel layer, forming a second nanostack of alternating layers of a second sacrificial material and a second channel layer on top of the first nanostack in which the second channel layers are thicker than the first silicon channel layers, forming first inner spacers between adjacent first silicon channel layers and second inner spacers between adjacent second channel layers by removing a portion of the first sacrificial material and the second sacrificial material, forming p-doped source drains in contact with the first silicon channel layers, forming n-doped source drains in contact with the second channel layers and over the p-doped source drains removing a remaining portion of the first sacrificial material and the second sacrificial material, trimming the first silicon channel layers, trimming the second channel layers, forming a silicon germanium cladding layer on the first silicon channel layers to form a first channel layer, and forming a gate material around the first channel layer and the second channel layers.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 is a cross-section view of at a starting point in the method of making the semiconductor structure in accordance with an aspect of the invention;

FIGS. 2A-2C are top down, cross-section along the X-direction and cross-section along the Y-direction of the semiconductor structure of FIG. 1, respectively, after patterning active area fins from the nanostack alternating layers in accordance with aspects of the invention;

FIGS. 3A-3C are top down, cross-section along the X-direction and cross-section along the Y-direction of the semiconductor structure of FIGS. 2A-2C, respectively, after forming dummy gates in accordance with aspects of the invention;

FIGS. 4A-4C are top down, cross-section along the X-direction and cross-section along the Y-direction of the semiconductor structure of FIGS. 3A-3C, respectively, after removing heavily doped layers in accordance with aspects of the invention;

FIGS. 5A-5C are top down, cross-section along the X-direction and cross-section along the Y-direction of the semiconductor structure of FIGS. 4A-4C, respectively, after forming gate sidewall spacers and dielectric layers in accordance with aspects of the invention;

FIGS. 6A-6C are top down, cross-section along the X-direction and cross-section along the Y-direction of the semiconductor structure of FIGS. 5A-5C, respectively, after forming inner spacers and source drains in accordance with aspects of the invention;

FIGS. 7A-7C are top down, cross-section along the X-direction and cross-section along the Y-direction of the semiconductor structure of FIGS. 6A-6C, respectively, after removing alternating layers of sacrificial layers from the nanostacks in accordance with aspects of the invention;

FIGS. 8A-8C are top down, cross-section along the X-direction and cross-section along the Y-direction of the semiconductor structure of FIGS. 7A-7C, respectively, after trimming channel layers in the nanostacks in accordance with aspects of the invention;

FIGS. 9A-9C are top down, cross-section along the X-direction and cross-section along the Y-direction of the semiconductor structure of FIGS. 8A-8C, respectively, after forming cladding layers in the nanostacks in accordance with aspects of the invention;

FIGS. 10A-10C are top down, cross-section along the X-direction and cross-section along the Y-direction of the semiconductor structure of FIGS. 9A-9C, respectively, after forming an optical planarization layer over the first nanostack in accordance with aspects of the invention;

FIGS. 11A-11C are top down, cross-section along the X-direction and cross-section along the Y-direction of the semiconductor structure of FIGS. 10A-10C, respectively, after removing the cladding from the second nanostack in accordance with aspects of the invention;

FIGS. 12A-12C are top down, cross-section along the X-direction and cross-section along the Y-direction of the semiconductor structure of FIGS. 11A-11C, respectively, removing the optical planarization layer in accordance with aspects of the invention;

FIGS. 13A-13C are top down, cross-section along the X-direction and cross-section along the Y-direction of the semiconductor structure of FIGS. 12A-12C, respectively, after forming gate material over the nanostacks in accordance with aspects of the invention;

FIG. 14 is an enlarged cross-section along the X-direction of FIG. 13A depicting features of merit in accordance with aspects of the invention; and

FIG. 15 is an enlarged cross-section along the Y-direction of FIG. 13B depicting certain features in accordance with aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

In summary, aspects of the invention include a semiconductor structure including a substrate 100, a nanostack 121 (also referred to as first channel stack) on the substrate 100 having one or more first channel layers 114-P and having a first channel layer width 1501, a second nanostack 122 (also referred to as second channel stack) having one or more second channel layers 114-2 and having a second channel layer width 1502 wherein the second nanostack 122 is vertically aligned above the first nanostack 121, and in which the first channel layer width 1501 is greater than the second channel layer width 1502. The first nanostack 121 can be part of a p-type field effect transistor while the second nanostack 122 can be part of an n-type field effect transistor. The technical benefits include enabling of further scaling of readily manufacturable semiconductor structures by reducing transistor cell size by allowing stacking of FETs with channels using different orientations.

Optionally, the semiconductor structure can further include a middle dielectric isolation layer 502 separating the first nanostack 121 and the second nanostack 122. The second channel layer width 1502 can be less than the width of the middle dielectric isolation layer 502. However, the first channel layer width 1501 can be the same as the width of the middle dielectric isolation layer 502. The technical benefits include enablement of robust manufacturing of the semiconductor structure having the technical benefits described previously.

In addition, optionally, the semiconductor structure can further include a lower dielectric isolation layer 501 separating the first nanostack 121 and the substrate 100. The second channel layer width 1502 can be less than the width of the lower dielectric isolation layer 501. The first channel layer width 1501 can be the same as the width of the middle dielectric isolation layer 502. The technical benefits include isolation of the channel stack and protection of the substrate during manufacturing of the semiconductor structure having the technical benefits described previously. The presence of a lower dielectric isolation layer 501 also enables future backside processing of the substrate 100.

Still optionally, the semiconductor structure can further include at least one first inner spacer 600-1 having a first inner spacer thickness 600-1T separating adjacent first channel layers 114-P, and at least one second inner spacer 600-2 having a second inner spacer thickness 600-2T separating adjacent second channel layers 114-2. The first inner spacer thickness 600-1T can be greater than the second inner spacer thickness 600-2T. The technical benefits include enabling manufacturing of stacked FETs having channels of different crystal orientations while also allowing similar performance in NFET and PFET.

Furthermore, the first channel layer 114-P has a first extension height 1301-HE between first inner spacers 600-1 and the second channel layer 114-2 has a second extension height 1302-HE between second inner spacers 600-2. The second extension height 1302-HE can be greater than the first extension height 1301-HE. The technical benefits include enabling channel layer thickness control to improving short channel effects.

Optionally, the semiconductor structure can further include a gate material around the first 114-P and second channel layers 114-2. The gate material can have a first suspension thickness 1401 located between adjacent first channel layers 114-P and a second suspension thickness 1401 located between adjacent second channel layers 114-2. The second suspension thickness 1402 is the same as the first suspension thickness 1401. The technical benefits of controlling spacing between adjacent channel layers is enablement of threshold voltage tuning of the different FETs.

Additionally, the second channel layer 114-2 has a channel region height 1302-HC surrounded by the gate material and the second extension height 1302-HE is greater than the channel region height 1302-HC of the second channel layer 114-2. In addition, the first channel layers 114-P have a first channel height 1301-HC surrounded by the gate material and the first extension height 1301-HE is the same as the first channel height 1301-HC of the first channel layers 114-P. The first channel layers 114-P include silicon germanium cladding layer 900. The first channel layer comprises silicon germanium cladding layer. The technical benefits are enabling manufacturing of stacked FETs having channels of different crystal orientations while also allowing similar performance in NFET and PFET transistors by increasing the mobility of PFET carriers for the PFET channel while preserving the mobility of NFET carrier.

A semiconductor structure includes a substrate 100, a gate material, a p-type field effect transistor (PFET) on the substrate, an n-type field effect transistor (NFET) on the PFET, a middle dielectric isolation layer 502 separating the PFET stack and the NFET stack. The PFET includes a p-doped source drain and a first nanostack 121 (e.g. a PFET) which includes two or more first channel layers 114-P, each layer having two first extension regions 22-1 on either side of a first channel region 21-1, in which the first extension region 22-1 comprises silicon and the first channel region 21-1 comprises silicon germanium and in which the first extension region 22-1 and the first channel region 21-1 have the same height. The PFET also includes a first inner spacer 600-1 in contact with and above and below each first extension region 22-1. The gate material 1300 wraps the first channel region 21-1. The NFET includes an n-doped source drain; and a second nanostack 122 (e.g. an NFET stack) comprising two or more second silicon channel layers 114-2, each layer having two second extension regions 22-2 on either side of a second channel region 21-2, wherein a second extension region height 1302-HE is greater than a second channel region height 1302-HC. The NFET also includes a second inner spacer 600-2 in contact with and above and below each second extension region 22-2. The gate 1300 material wraps the second channel region 21-2. In which the second extension region height 1302-HE is greater than the first extension region height 1301-HE, a first inner spacer thickness 600-1T is greater than a second inner spacer thickness 600-2T, a second channel layer width 1502 is less than a middle dielectric isolation layer 502 width and a first channel layer width 1501 is the same as the middle dielectric isolation layer 502 width. The technical benefits include enabling of further scaling of readily manufacturable semiconductor structures by reducing transistor cell size, allow stacking of FETs with channels using different orientations while also allowing similar performance in NFET and PFET transistors by increasing the mobility of PFET carriers for the PFET channel while preserving the mobility of NFET carrier. In addition, improvements in short channel effects and threshold voltage tuning are also enabled.

The method of forming a stacked NFET on PFET on substrate 100, includes forming a first nanostack 121 of alternating layers of a first sacrificial material 112-1 and a first silicon channel layer 114-1, forming a second nanostack 122 of alternating layers of a second sacrificial material 112-2 and a second channel layer 114-2 on top of the first nanostack 121 in which the second channel layers 114-2 are thicker than the first silicon channel layers 114-1, forming first inner spacers 600-1 between adjacent first silicon channel layers 114-1 and second inner spacers 600-2 between adjacent second channel layers 114-2 by removing a portion of the first sacrificial material 112-1 and the second sacrificial material 112-2, forming p-doped source drains in contact with the first silicon channel layers 114-1, forming n-doped source drains in contact with the second channel layers 114-2 and over the p-doped source drains removing a remaining portion of the first sacrificial material 112-1 and the second sacrificial material 112-2, trimming the first silicon channel layers 114-1, trimming the second channel layers, forming a silicon germanium cladding layer 900 on the first silicon channel layers 114-1 to form a first channel layers 114-P, and forming a gate 1300 material around the first channel layers 114-P and the second channel layers 114-2. The technical benefits include enabling of further scaling of readily manufacturable semiconductor structures by reducing transistor cell size, allow stacking of FETs with channels using different orientations while also allowing similar performance in NFET and PFET transistors by increasing the mobility of PFET carriers for the PFET channel while preserving the mobility of NFET carrier.

In addition, a second extension height 1302-HE (also called second channel region height) under the second inner spacers 600-2 can be greater than a first extension height 1301-HE (also called first channel region height) under the first inner spacers 600-1. The technical benefit can include improved short channel effects as influenced by heights.

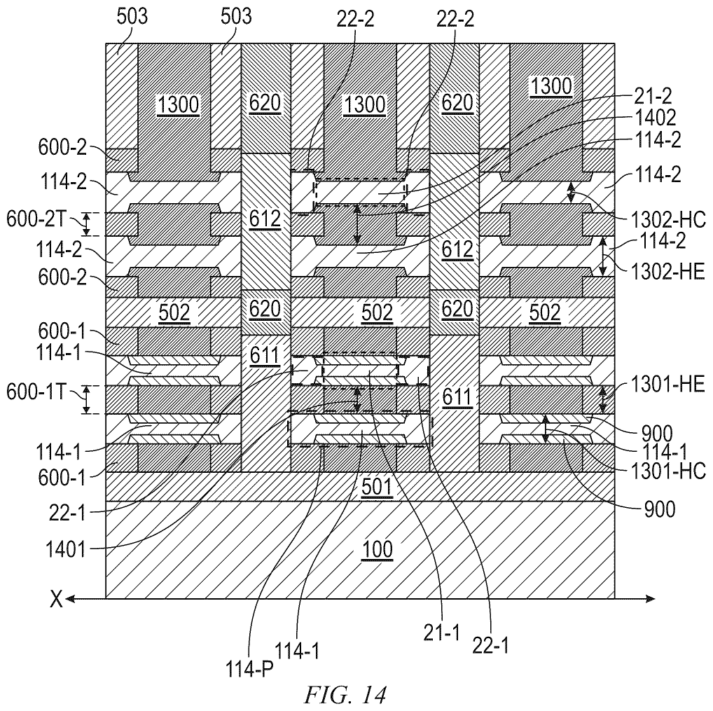

Furthermore, a first inner spacer thickness 600-1T between adjacent first channel layers 114-P can be greater than a second inner spacer thickness 600-2T between adjacent second channel layers 114-2 (See, FIG. 14). The technical benefits are enabling of further scaling of readily manufacturable semiconductor structures by reducing transistor cell size, allow stacking of FETs with channels using different orientations while also allowing similar performance in NFET and PFET transistors by increasing the mobility of PFET carriers for the PFET channel while preserving the mobility of NFET carrier.

The method may further include forming a middle dielectric layer 502 between the first nanostack 121 and the second nanostack 122. The technical benefits include enablement of robust manufacturing of the semiconductor structure having the technical benefits described previously.

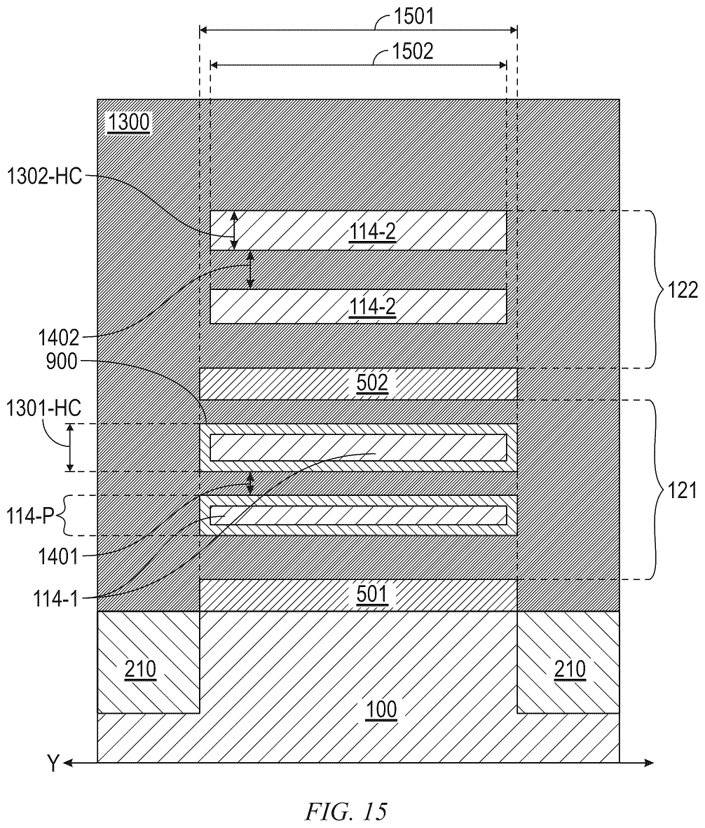

A second channel layer width 1502 can be less than a middle dielectric layer 502 width and less than a first channel layer width 1501 (See, FIG. 15). The technical benefits include enabling a robust manufacturing process.

Techniques as disclosed herein can provide substantial beneficial technical effects. Some embodiments may not have these potential advantages and these potential advantages are not necessarily required of all embodiments. By way of example only and without limitation, one or more embodiments may provide one or more of: allowing further scaling, enhanced yield, and/or enhanced reliability for semiconductor structures by reducing transistor cell size; allowing stacking of FETs with channels using different orientations; allowing similar performance in NFET and PFET transistors by increasing the mobility of PFET carriers for the PFET channel while preserving the mobility of NFET carrier; and/or providing structures that are readily manufacturable as they do not include major etch process changes.

Aspects of invention provide techniques for stacked GAA FETs on the same substrate. GAA transistors can be stacked on a monolithic substrate (as opposed to vertically bonding two transistors from separate substrates) to reduce the cell size thereby increasing performance. In the stacked configuration, oppositely doped transistors (i.e. NFET and PFET) are on top of each other. For example, the top nanosheet(s) can be connected to phosphorous-doped silicon source drains to form an NFET, and the bottom nanosheet(s) to boron-doped silicon germanium to form a PFET.

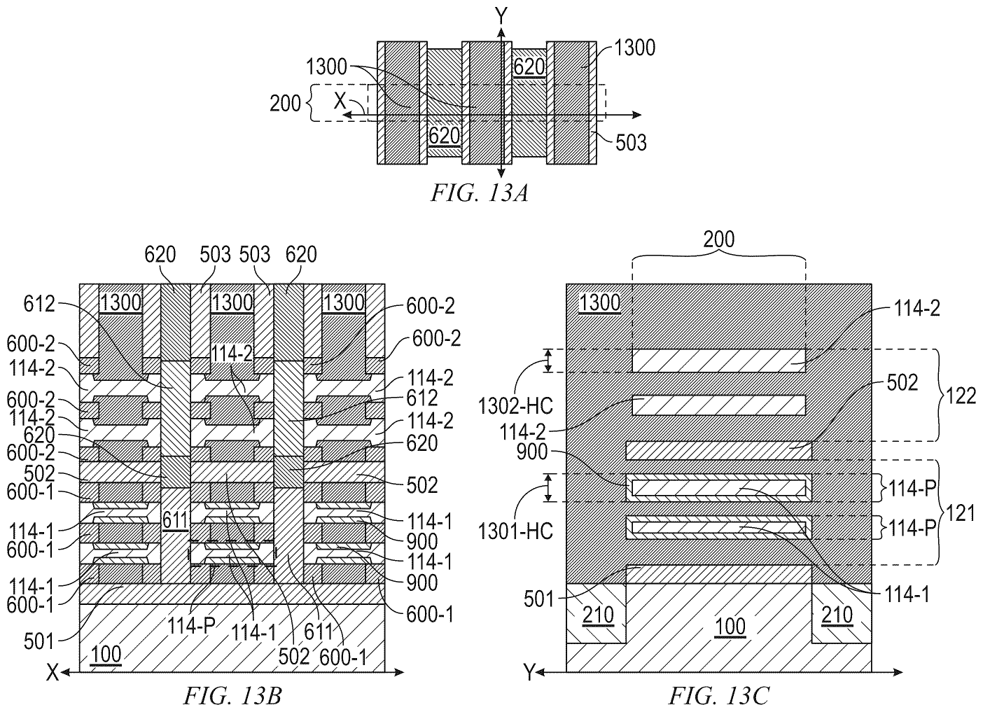

Referring now to FIGS. 13A-13C, an exemplary stacked FET structure according to aspects of the invention is depicted. FIG. 13A is a top-down view of a substrate with stacked FETs. Here, a series of gates 1300, each with sidewall spacers 503 are separated by a dielectric layer 620. Perpendicular to gates 1300 and underlying the gates is an active area fin 200. Cross-sections in the X-direction along the active area fin 200 are in the “B” features of the disclosure. Similarly, cross-sections in the Y-direction along gate 1300 are in the “C” features of the disclosure.

Referring to FIG. 13B, an X-direction cross-section along the active area fin 200, the stack structure is on a substrate 100 which can be a semiconductor. A lower dielectric isolation layer 501 is on the substrate and a middle dielectric layer 502 is above the lower dielectric isolation layer 501. Below the middle dielectric layer 502 is the first FET and above it is the second FET. The first FET, vertically sandwiched by the two dielectric layers, namely the lower dielectric isolation layer 501 and the middle dielectric layer 502, includes first channel layers 114-P, a gate 1300, and first source drain 611. In the first FET, first inner spacers 600-1 isolate the gate 1300 from the first source drain 611 and isolated adjacent first channel layers 114-P from each other.

Continuing to refer to FIG. 13B, and referring also to FIG. 14, which is a reproduction of FIG. 13B with further features noted, the first channel layers 114-P can be made from two materials, namely, a first silicon channel layer 114-1 material and a silicon germanium cladding layer 900. The cladding layer 900 can be on a portion of the first silicon channel material 114-1. In other embodiments, the first channel layers 114-P can be a more uniform silicon germanium distributed by annealing into the silicon channel material, as opposed to the stark contrast depicted in FIGS. 13B and 14.

Still referring to FIG. 14, the first channel layer 114-P can be viewed as having two regions, and a first extension region 22-1 under the first inner spacers 600-1 and a first channel region 21-1 wrapped by the gate 1300. In the first FET, the first extension region height 1301-HE and the first channel region height 1301-HC can be the same within process tolerances. Thus, the first channel layers 114-P, which includes cladding layer 900, is not dumbbell shaped. The thickness of the gate 1300 material between adjacent first channel layers 114-P can be referred to as the first suspension thickness 1401 and is the same (within process tolerances) as the first inner spacer thickness 600-1T. In embodiments in which there is only one channel layer in a given stack, the suspension thickness can be viewed as the thickness of gate 1300 material between the channel layer and adjacent structure such as the substrate, middle dielectric layer 502, lower dielectric layer 501 or the like.

Still referring to FIG. 14, above the first FET and the middle dielectric layer 502 is the second FET. The second FET includes second channel layers 114-2, a gate 1300 and second source drain 612. In the second FET, second inner spacers 600-2 isolate the gate 1300 from the second source drain 612 and isolated adjacent second channel layers 114-2 from each other. A common gate is shown in the example but in other embodiments, separate dedicated gates can be employed for the NFET and PFET.

The second channel layers 114-2 can be made from one material, for example a semiconductor such as silicon. Like the first channel layers 114-P, the second channel layer 114-2 can be viewed as having two regions, and a second extension region 22-2 under and in direct contact with the second inner spacers 600-2 and a second channel region 21-2 wrapped by the gate 1300. In the second FET, the second extension region height 1302-HE and the second channel region height 1302-HC can be different with the second extension region height 1302-HE being greater than the second channel region height 1302-HC. Thus, the second channel layers 114-2 can be dumbbell shaped. The thickness of the gate 1300 material between adjacent second channel layers 114-2 can be referred to as the second suspension thickness 1402 and can be greater than the second inner spacer thickness 600-2T.

Staying with FIG. 14, more relative dimensions are to be noted between the FETs. The first inner spacers 600-1, and second inner spacers 600-2 of the first and second FETs can have different thicknesses. Advantageously, the first inner spacer thickness 600-1T can be greater than the second inner spacer thickness 600-2T. Moving to the suspension thicknesses, the first suspension thickness 1401 can be about the same as the second suspension thickness 1402. Moving to channel layers, the height of the extension regions in the two FETs can be different with the first extension region height 1301-HE being less than the height of the second extension region 1302-HE. The height of the channel regions in the two FETs can be different with the first channel region height 1301-HC being greater than the second extension region height 1302-HE.

Turn now to FIG. 13C, which is an exemplary cross-section in the y-direction along gate 1300. Here, substrate 100 contains shallow trench isolations 210 located on either side of the active area fin 200. The active area fin 200 contains a first nanostack 121 of first channel layers 114-P and a second nanostack 122 of second channel layers 114-2, respectively. The first nanostack 121 and the second nanostack 122 are separated by middle dielectric layer 502. The first nanostack 121 is separated from the substrate 100 by lower dielectric isolation layer 501. The first channel layers 114-P and second channel layers 114-2 are wrapped by gate 1300 material, which includes one or more of gate oxides, high-k dielectrics, work function (WF) layers and metal fill. In this Y-direction cross-section, the first channel layers 114-P and the second channel layers 114-2 are surrounded by the gate 1300 and are also attached to the relevant first source drains 611 or second source drain 612 behind and in front of the plane of FIG. 13C.

In FIG. 13C the cross-section is through the first channel region 21-1 and second channel region 21-2 of the channel layers 114, therefore the heights are the first channel region height 1301-HC and second channel region height 1302-HC, respectively. Moving to FIG. 15 which is the same cross-section as FIG. 13C but highlights additional features, first suspension thickness 1401 and second suspension thicknesses 1402 are shown. As pointed out in FIG. 14, the first suspension thickness 1401 can be less than the second suspension thickness 1402. Turning from heights of features to widths of features, the first channel layer width 1501 is greater than the second channel layer width 1502. The width of the lower dielectric isolation layer 501 and the middle dielectric layer 502 is the same, within process tolerances, as the first channel layer width 1501.

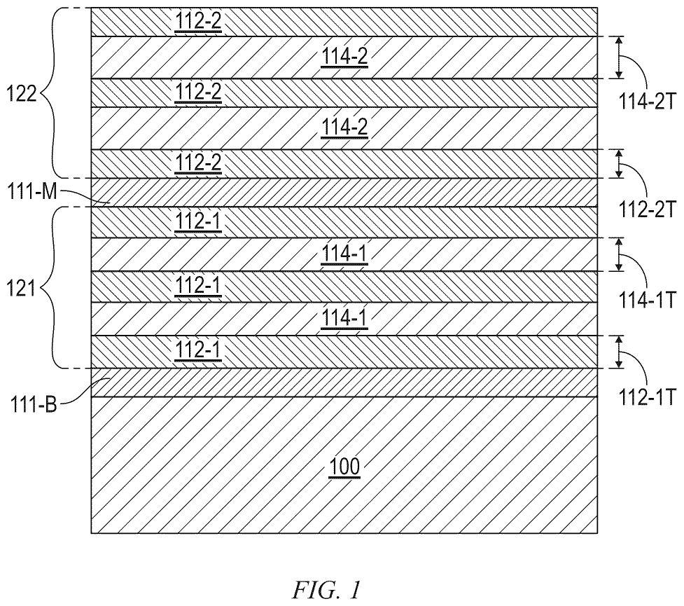

A first exemplary process flow for making the structures of FIGS. 13A-15 can begin at FIG. 1 in which a first nanostack 121 and a second nanostack 122 of alternating materials are on a substrate 100. The nanostacks are separated from each other and the substrate 100 by a heavily doped layer, 111-M and 111-B, respectively. The heavily doped layer can be, for example, a silicon germanium layer with enough germanium to be removed selectively from the nanostacks. At this point of the process, the nanostacks are made of first and second alternating layers of silicon and first and second alternating layers of sacrificial material which can be silicon germanium. The alternating layers of silicon, after processing, will become the channel layers. Specifically, in the second nanostack 122, the alternating layers of silicon are the second channel layers 114-2; In the first nanostack 121, the alternating layers will be part of the first channel layers 114-P of FIGS. 13A-15, specifically the first silicon channel layer 114-1 material. As such, the silicon alternating layers of the first nanostack 121 have a first thickness 114-1T which is less than the second thickness 114-2T of the silicon alternating layers (i.e. future second channel layer) of the second nanostack 122. The first sacrificial thickness 112-1T of the alternating layers of sacrificial material 112 of the first nanostack 121 is greater than the second sacrificial thickness 112-2T of the alternating layers of sacrificial materials 112 of the second nanostack 122. The alternating layers of sacrificial material 112 will be removed later in the process. It should be noted that while silicon and silicon germanium are identified, other semiconductor materials with appropriate doping for NFET and PFET devices can also be used.

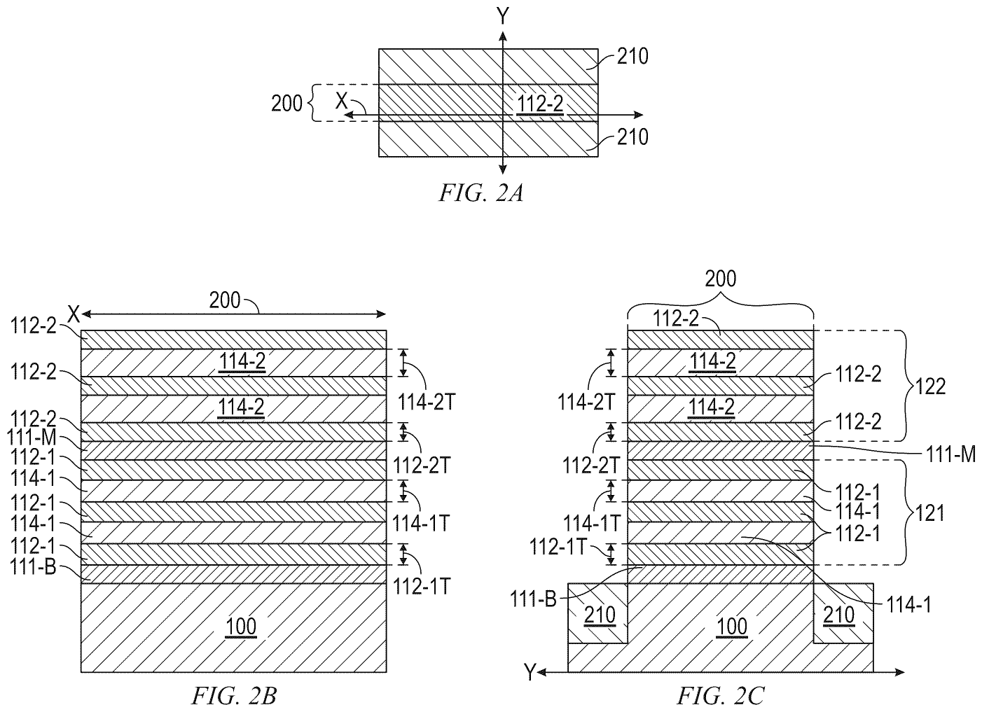

In FIGS. 2A-2C, the blanket layers of films of FIG. 1 are patterned to form an active area fin 200 on the substrate 100 and flanked by shallow trench isolations 210 in the substrate 100.

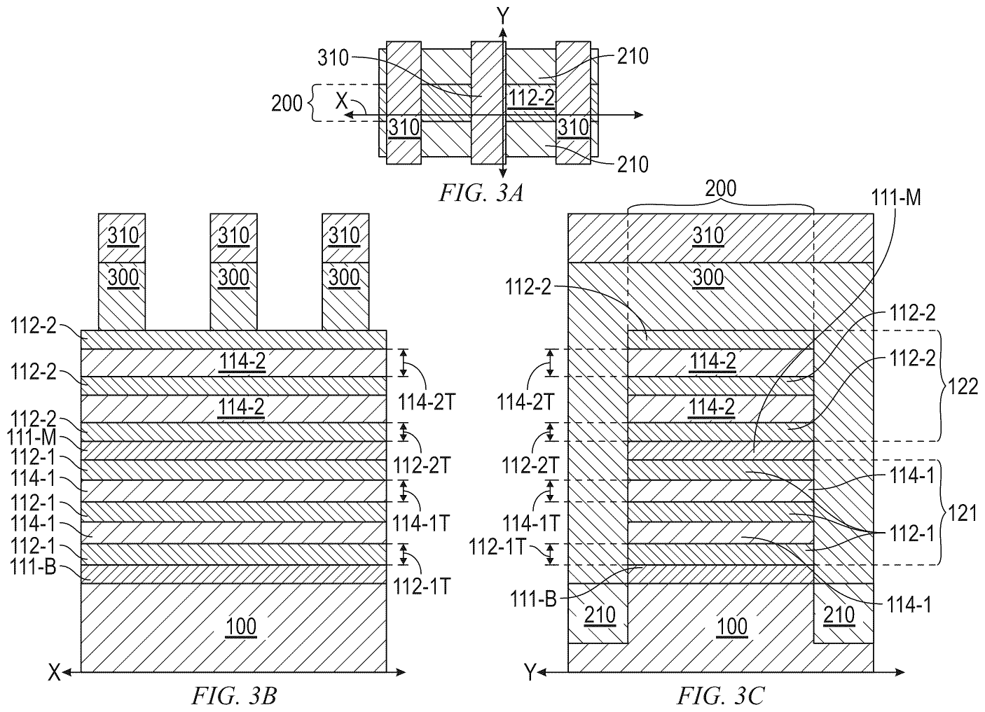

In FIGS. 3A-3C, one or more dummy gates 300 with hardmask 310 is/are formed over the substrate 100 and active area fin 200. The patterned dummy gates 300 run perpendicular to the active area fin 200.

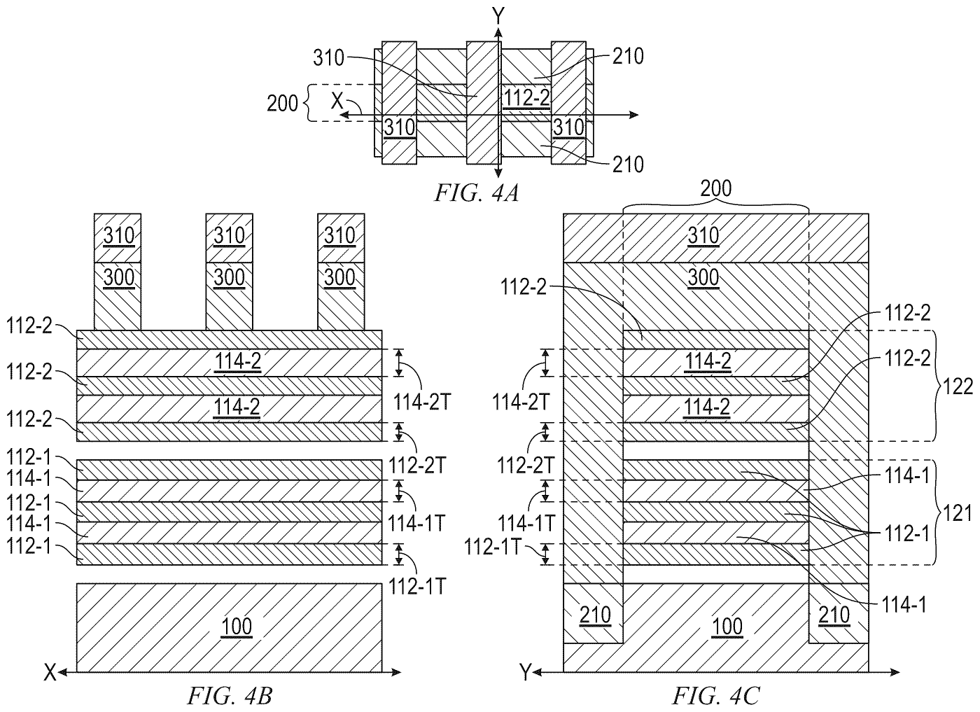

In FIGS. 4A-4C, each heavily doped layer 111-M and 111-B is removed selectively using known selective etching techniques. To achieve selectivity, the heavily doped layer can have at least 120% of the germanium concentration of the sacrificial material. In some embodiments, the heavily doped layer can have a germanium concentration around 50%. Generally, given the teachings herein, the skilled person can select appropriate etchants and layers with appropriate percentages of Germanium to permit selective etching as described.

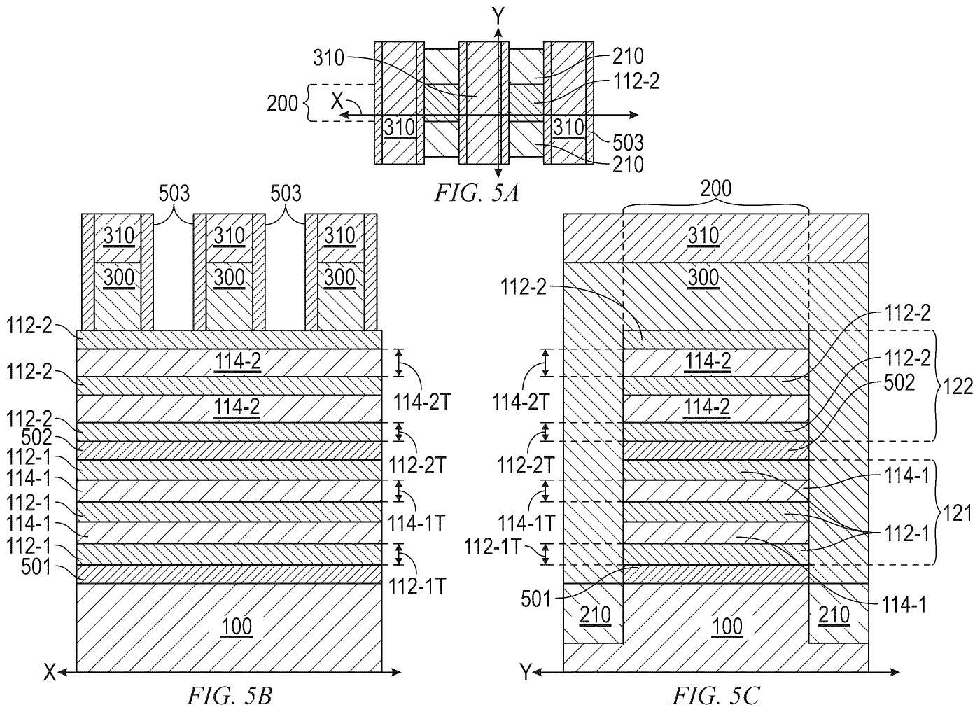

In FIGS. 5A-5C, a dielectric film is deposited and anisotropically etched and/or polished to form sidewall spacers 503 flanking the dummy gates 300/hardmask 310 structures. The deposited dielectric film also fills the voids left by the removal of each heavily doped layer 111-M and 111-B to form the middle dielectric layer 502 between first nanostack 121 and second nanostack 122 and lower dielectric isolation layer 501 between the first nanostack 121 and the substrate 100.

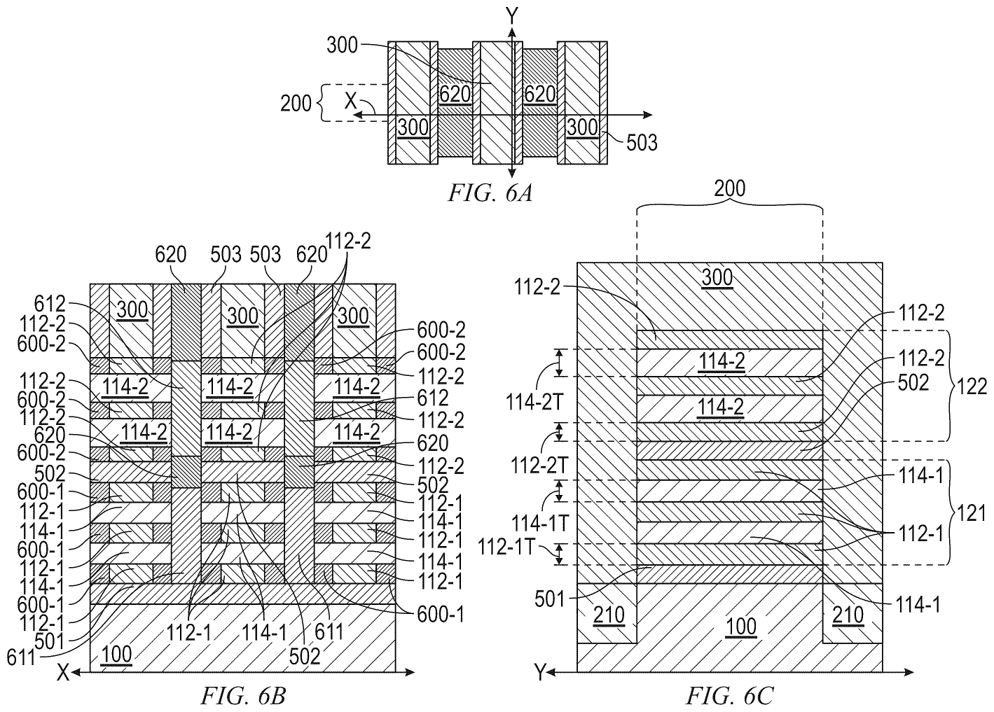

In FIGS. 6A-6C, the first nanostack 121 and second nanostack 122 areas exposed between the gate sidewall spacers are etched down to the lower dielectric isolation layer 501. The etching creates exposed edges of the alternating layers of sacrificial material which are then recessed horizontally to form a cavity under the sidewall spacers 503. The cavity is then filled with a dielectric material to create first inner spacers 600-1 and second inner spacers 600-2 of the first nanostack 121 and second nanostack 122, respectively. Next, first source drain 611 region and a dielectric layer 620 are formed followed by a second source drain 612 region and a dielectric layer 620 resulting in a dielectric layer 620 formed above the second source drain 612 and between first source drain 611 and the second source drain 612. The dielectric layer is planarized to be co-planar with the dummy gates 300.

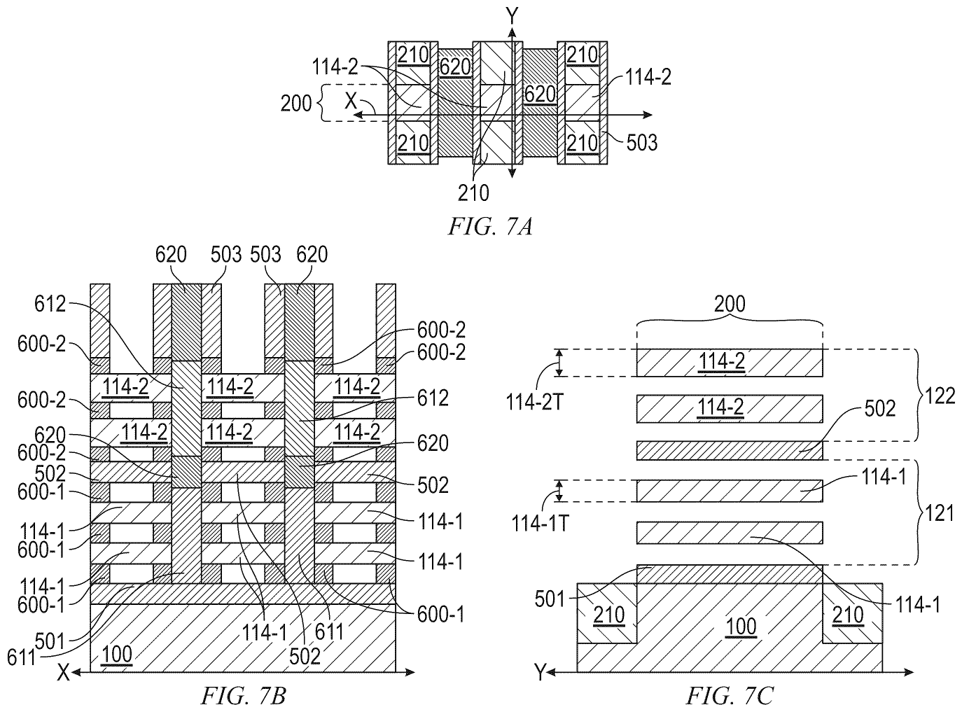

In FIGS. 7A-7C, the dummy gates 300 and alternating layers of sacrificial material 112 (which includes first sacrificial material 112-1 and second sacrificial material 112-2 of the first nanostack 121 and second nanostack 122, respectively) are removed, thereby exposing surfaces of the channel layers 114 (which at his point in the process includes second channel layers 114-2 of the second nanostack 122 and first silicon channel layer 114-1 material of the first nanostack 121).

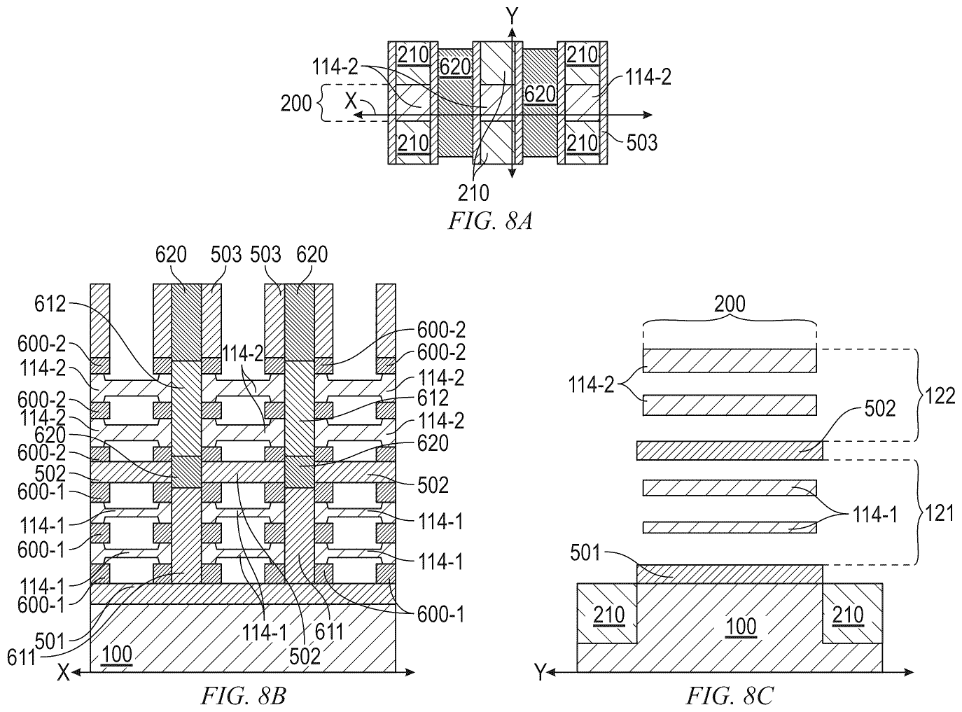

In FIGS. 8A-8C, trimming the channel layers 114 occurs by etching the exposed silicon resulting in a “dog bone” (See. FIG. 8B) structure. In a dog bone structure, regions under the first inner spacers 600-1 and second inner spacers 600-2 can be “fatter” while regions in the center (i.e. what will become the channel region when the gate if formed) are thinned.

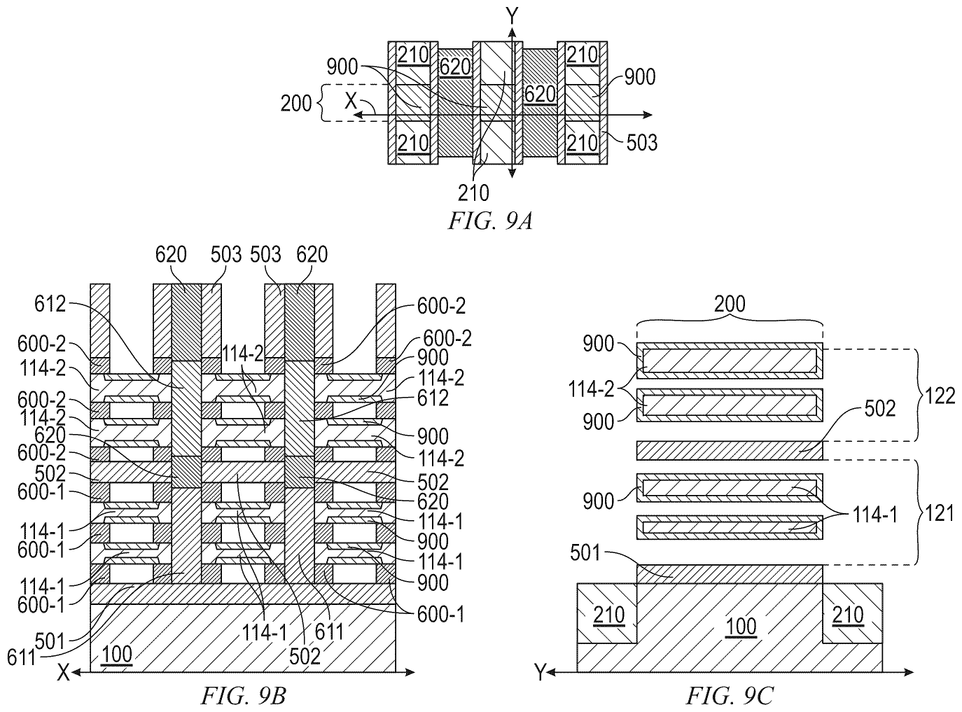

In FIGS. 9A-9C, a silicon germanium cladding layer 900 is formed on the exposed surfaces of the trimmed channel layers 114.

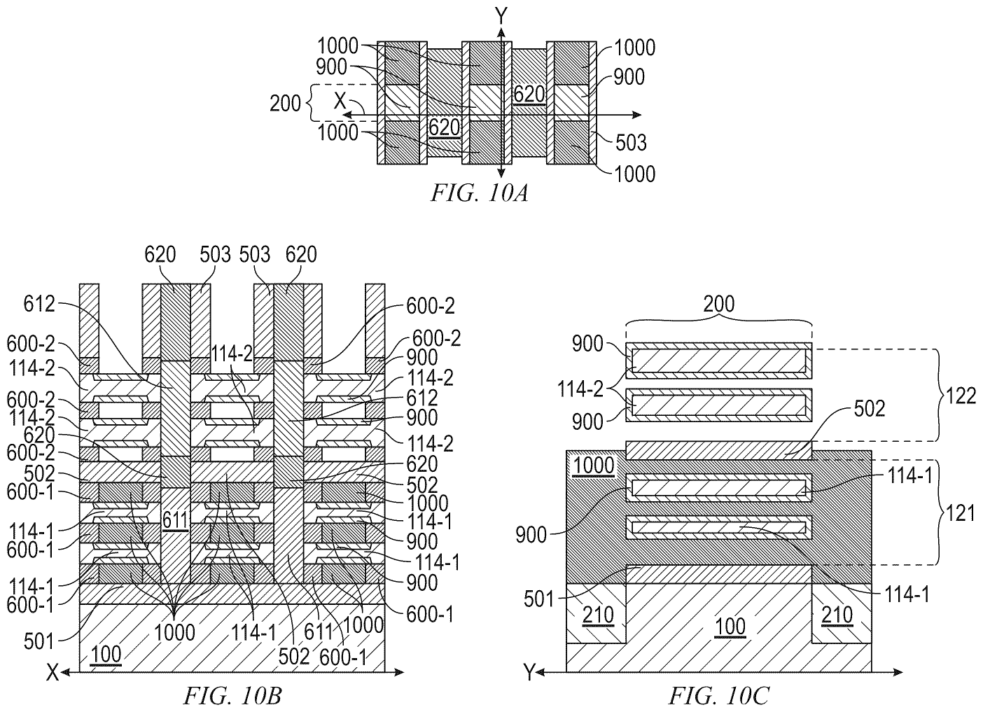

In FIGS. 10A-10C, an optical planarization layer 1000 is formed over the structures of FIG. 9A-9C and recessed to the level of the middle dielectric layer 502, thereby protecting the first nanostack 121 and exposing the second nanostack 122.

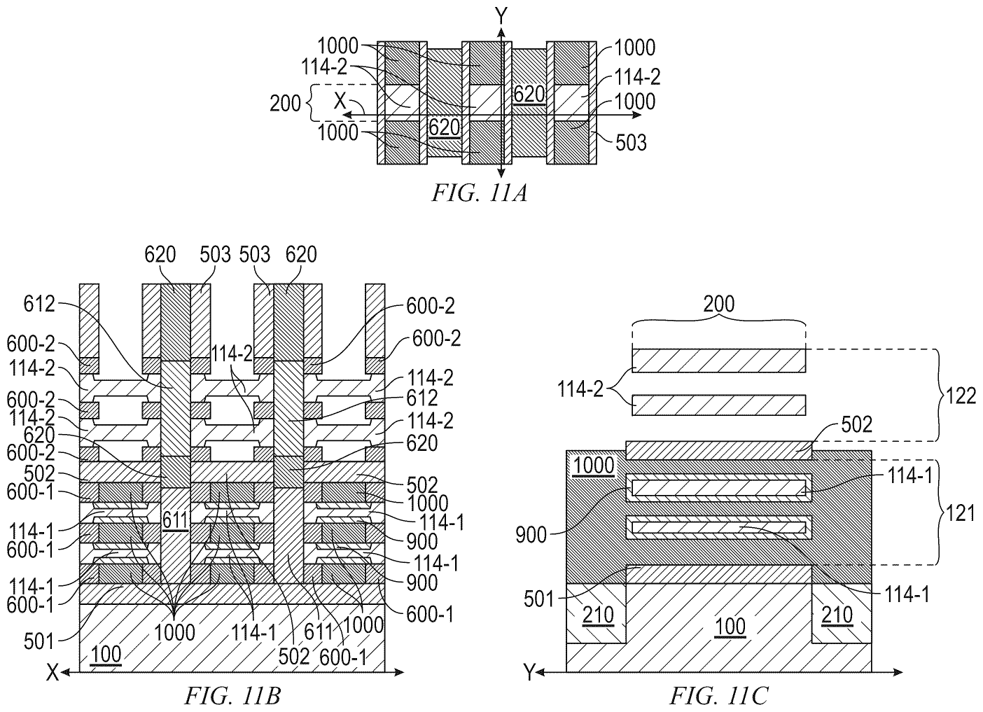

In FIGS. 11A-11C, the silicon germanium cladding layer 900 is removed from the exposed second nanostack 122. The protected first nanostack 121 retains the cladding layer 900.

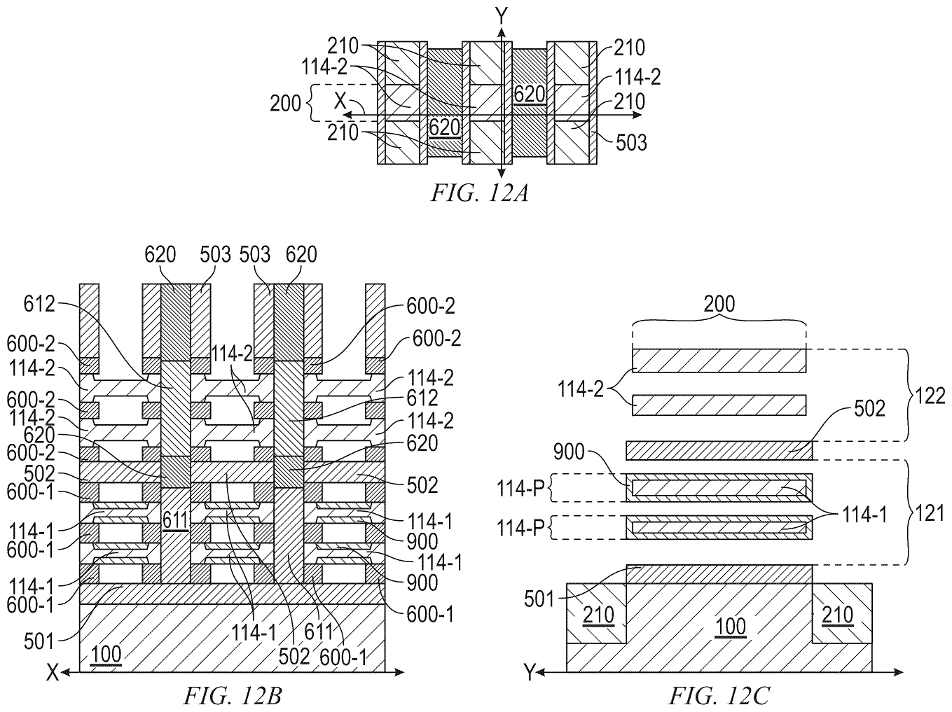

In FIGS. 12A-12C, the optical planarization layer 1000 is removed to allow gate 1300 material to be deposited around the first nanostack 121 and the second nanostack 122 (see FIGS. 13A-13C). Now, the second alternating silicon layer(s) has/have become the second channel layer(s) 114-2 for the second transistor, an NFET in this example. Likewise, silicon germanium cladded first alternating silicon layer(s) has/have become the first channel layers 114-P of the first transistor, a PFET in this example.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for case of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
a substrate;
a first channel stack on the substrate having one or more first channel layers and having a first width;
a second channel stack having one or more channel layers and having a second width wherein the second channel stack is vertically aligned above the first channel stack; and
wherein the first width is greater than the second width.

2. The semiconductor structure of claim 1 wherein the first channel stack is part of a p-type field effect transistor and the second channel stack is part of an n-type field effect transistor.

3. The semiconductor structure of claim 1 further comprising:
a middle dielectric isolation layer separating the first channel stack and the second channel stack.

4. The semiconductor structure of claim 3, wherein the middle dielectric isolation layer has a width, and wherein the second width is less than the width of the middle dielectric isolation layer.

5. The semiconductor structure of claim 4 wherein the first width is the same as the width of the middle dielectric isolation layer.

6. The semiconductor structure of claim 1 further comprising:
a lower dielectric isolation layer separating the first channel stack and the substrate.

7. The semiconductor structure of claim 6 wherein the lower dielectric isolation layer has a width, and wherein the second width is less than the width of the lower dielectric isolation layer.

8. The semiconductor structure of claim 7 wherein the first width is the same as a width of a middle dielectric isolation layer separating the first channel stack and the second channel stack.

9. The semiconductor structure of claim 1 further comprising:
at least one first inner spacer having a first thickness separating adjacent first channel layers; and
at least one second inner spacer having a second thickness separating adjacent second channel layers;
wherein the first thickness is greater than the second thickness.

10. The semiconductor structure of claim 9, wherein:
the one or more first channel layers has a first extension height between the at least one first inner spacers;
the one or more second channel layers has a second extension height between the at least one second inner spacers; and
the second extension height is greater than the first extension height.

11. The semiconductor structure of claim 10, further comprising a gate material around the one or more first channel layers and the one or more second channel layers, wherein:
the gate material has a first suspension thickness in the first nanostack;
the gate material has a second suspension thickness in the second nanostack; and
the second suspension thickness is the same as the first suspension thickness.

12. The structure of claim 11, wherein:
the second channel layer has a channel height surrounded by the gate material; and
the second extension height is greater than the channel height of the second channel layer.

13. The structure of claim 11, wherein:
the first channel layer has a first channel height surrounded by the gate material; and
the first extension height is the same as the first channel height of the first channel layer.

14. The structure of claim 13, wherein the first channel layer comprises silicon germanium cladding layer.

15. A semiconductor structure comprising:
a substrate;
a gate material;
a p-type field effect transistor (PFET) on the substrate, comprising:
a p-doped source drain;
a PFET stack comprising two or more first channel layers, each layer having two first extension regions on either side of a first channel region, wherein the first extension region comprises silicon and the first channel region comprises silicon germanium and wherein the first extension region and the first channel region have a same height; and
a first inner spacer in contact with and above and below each first extension region;
wherein the gate material wraps the first channel region;
an n-type field effect transistor (NFET) on the PFET comprising:
an n-doped source drain; and
an NFET stack comprising two or more silicon channel layers, each layer having two second extension regions on either side of a second channel region, wherein a second extension region height is greater than a second channel region height;
a second inner spacer in contact with and above and below each second extension region; and
wherein the gate material wraps the second channel region; and
a middle dielectric isolation layer separating the PFET stack and the NFET stack;
wherein the second extension region height is greater than the first extension region height;
wherein a first inner spacer thickness is greater than a second inner spacer thickness;
wherein a second channel layer width is less than a middle dielectric isolation width; and
wherein a first channel layer width is the same as a width of the middle dielectric isolation layer.

16. A method of forming a stacked NFET on PFET on substrate, the method comprising:
forming a first nanostack of alternating layers of a first sacrificial material and a first silicon channel layers;
forming a second nanostack of alternating layers of a second sacrificial material and a second channel layers on top of the first nanostack wherein the second channel layers are thicker than the first silicon channel layers;
forming first inner spacers between adjacent first silicon channel layers and second inner spacers between adjacent second channel layers by removing a portion of the first sacrificial material and the second sacrificial material;
forming p-doped source drains in contact with the first silicon channel layers;
forming n-doped source drains in contact with the second channel layers and over the p-doped source drains;
removing a remaining portion of the first sacrificial material and the second sacrificial material;
trimming the first silicon channel layers;
trimming the second channel layers;
forming a silicon germanium cladding layer on the first silicon channel layers to form a first channel layer; and
forming a gate material around the first channel layers and the second channel layers.

17. The method of claim 16, wherein a second channel region height under the second inner spacers is greater than a first channel region height under the first inner spacers.

18. The method of claim 16, wherein a first inner spacer thickness between adjacent first channel layers is greater than a second inner spacer thickness between adjacent second channel layers.

19. The method of claim 16, further comprising:
forming a middle dielectric layer between the first nanostack and the second nanostack.

20. The method of claim 19, wherein a second channel layer width is less than a middle dielectric layer width and less than a first channel layer width.
